(19) United States
(12) Patent Application Publication
(10) Pub. No.: US 2025/0386631 A1
(43) Pub. Date: Dec. 18, 2025

(54) MICRO LED DISPLAY PANEL AND DISPLAY DEVICE

(71) Applicant: JADE BIRD DISPLAY (SHANGHAI) LIMITED, SHANGHAI (CN)

(72) Inventors: Zhichen GU, Shanghai (CN); Weisin TAN, Shanghai (CN)

(21) Appl. No.: 19/235,613

(22) Filed: Jun. 12, 2025

(30) Foreign Application Priority Data
Jun. 14, 2024 (WO) PCT/CN2024/099240

(51) Int. Cl. H10H 29/14; H10H 29/80

(52) U.S. Cl. CPC H10H 29/142; H10H 29/8323; H10H 29/8325; H10H 29/842

(57) ABSTRACT

A micro LED display panel and a display device are provided. The micro LED display panel includes: a plurality of micro LED elements each including a first semiconductor layer, a light emitting layer, and a second semiconductor layer stacked from top down; and a plurality of contact pads each arranged between adjacent micro LED elements of a part of the plurality of micro LED elements and conductively coupled to the respective first semiconductor layers of the adjacent micro LED elements.

### CROSS-REFERENCE TO RELATED APPLICATIONS

The present disclosure claims the benefit of priority to PCT Application No. PCT/CN2024/099240, filed on Jun. 14, 2024, which is incorporated herein by reference in its entirety.

### TECHNICAL FIELD

The present disclosure generally relates to micro display technology, and more particularly, to a micro light emitting diode (LED) display panel and a display device.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. A micro LED display panel is manufactured by integrating an array of thousands or even millions of micro LEDs with an integrated circuit (IC) back panel. In conventional techniques, contact pads may be arranged between every pair of adjacent micro LED elements for increasing electrical conductivity. Since the dense arrangement of contact pads may shade light emitted by the micro LED elements, it may deteriorate the displaying quality of the micro LED elements and display panel.

Therefore, there is a need for improving the displaying quality of micro LEDs.

### SUMMARY OF THE DISCLOSURE

Some embodiments of the present disclosure provide a micro LED display panel. The micro LED display panel includes a plurality of micro LED elements each comprising a first semiconductor layer, a light emitting layer, and a second semiconductor layer stacked from top down; and a plurality of contact pads each arranged between adjacent micro LED elements of a part of the plurality of micro LED elements and conductively coupled to the respective first semiconductor layers of the adjacent micro LED elements.

Some embodiments of the present disclosure provide a display device. The display device includes any of the micro LED described herein or any of the micro LED display panels described herein.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1A illustrates a structural diagram showing a sectional view of an exemplary micro LED display panel, according to some embodiments of the present disclosure.

FIG. 1B illustrates a structural diagram showing a top view of the exemplary micro LED display panel shown in FIG. 1A, according to some embodiments of the present disclosure.

FIG. 2A illustrates a structural diagram showing a top view of another exemplary micro LED display panel, according to some embodiments of the present disclosure.

FIG. 2B illustrates a structural diagram showing a top view of another exemplary micro LED display panel, according to some embodiments of the present disclosure.

FIG. 2C illustrates a structural diagram showing a top view of another exemplary micro LED display panel, according to some embodiments of the present disclosure.

FIG. 2D illustrates a structural diagram showing a top view of another exemplary micro LED display panel, according to some embodiments of the present disclosure.

FIG. 2E illustrates a structural diagram showing a top view of another exemplary micro LED display panel, according to some embodiments of the present disclosure.

FIG. 2F illustrates a structural diagram showing a top view of another exemplary micro LED display panel, according to some embodiments of the present disclosure.

FIG. 3A illustrates a structural diagram showing a sectional view of another exemplary micro LED display panel, according to some embodiments of the present disclosure.

FIG. 3B illustrates a structural diagram showing a top view of the exemplary micro LED display panel shown in FIG. 3A, according to some embodiments of the present disclosure.

FIG. 4A illustrates a structural diagram showing a sectional view of another exemplary micro LED display panel, according to some embodiments of the present disclosure.

FIG. 4B illustrates a structural diagram showing a top view of the exemplary micro LED display panel shown in FIG. 4A, according to some embodiments of the present disclosure.

FIG. 5 illustrates a structural diagram showing a sectional view of another exemplary micro LED display panel, according to some embodiments of the present disclosure.

FIG. 6A illustrates a structural diagram showing a sectional view of another exemplary micro LED display panel, according to some embodiments of the present disclosure.

FIG. 6B illustrates a structural diagram showing a top view of the exemplary micro LED display panel shown in FIG. 6A, according to some embodiments of the present disclosure.

FIG. 7 illustrates an exemplary display device, according to some embodiments of the present disclosure.

FIG. 8 illustrates another exemplary display device, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

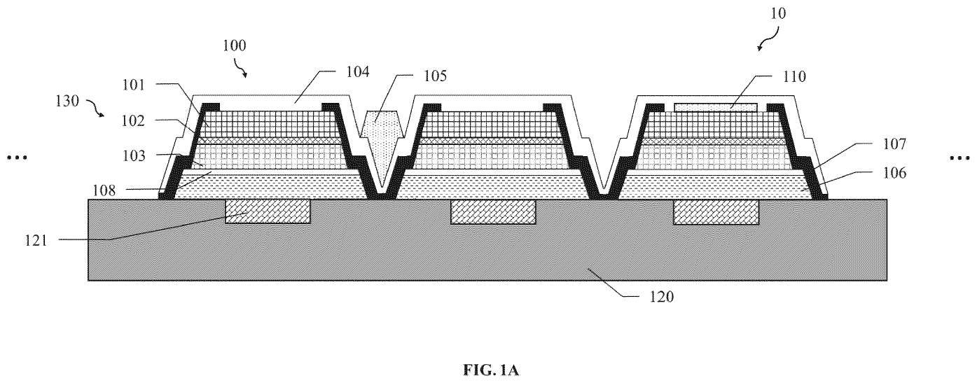

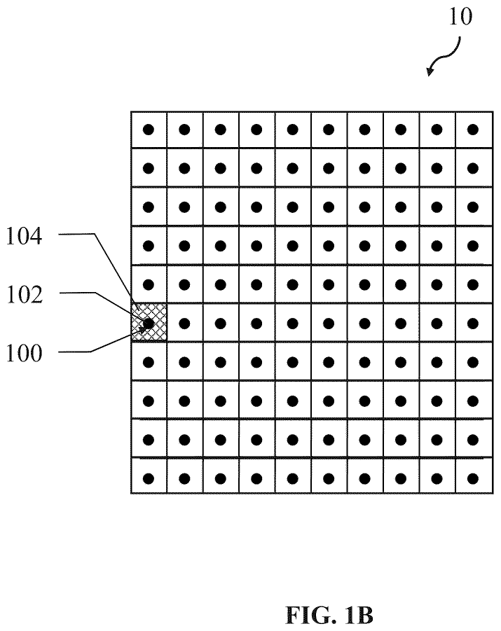

FIG. 1A illustrates a structural diagram showing a sectional view of an exemplary micro LED display panel 10, according to some embodiments of the present disclosure. Micro LED display panel 10 includes a plurality of micro LED elements 100 and a plurality of contact pads 105. It can be understood that in FIG. 1A, micro LED display panel 10 including three micro LED elements 100 and one contact pad 105 is shown only for illustrative purposes. The structure shown can be extended to form a complete micro LED display panel 10.

As shown in FIG. 1A, each micro LED element 100 includes a first semiconductor layer 101, a light emitting layer 102, and a second semiconductor layer 103. First semiconductor layer 101, light emitting layer 102, and second semiconductor layer 103 are stacked from top down to form a mesa 130. The sidewall of mesa 130 is inclined.

In some embodiments, second semiconductor layer 103 can be a P-type epitaxial layer or an N-type epitaxial layer. First semiconductor layer 101 can be an N-type epitaxial layer or a P-type epitaxial layer. A material of first semiconductor layer 101 is selected from one or more of GaN, InGaN, AlInGaN, AlGaN, GaP, AlGaInP, or AlInP. Light emitting layer 102 is a quantum well layer. A material of light emitting layer 102 is selected from one or more of InGaN, AlGaN, AlInGaN, InGaP or AlGaInP. First semiconductor layer 101 and second semiconductor layer 103 have opposite conductive types. That is, if first semiconductor layer 101 is a P-type epitaxial layer, then second semiconductor layer 103 is an N-type epitaxial layer; and if first semiconductor layer 101 is an N-type epitaxial layer, then second semiconductor layer 103 is a P-type epitaxial layer. A material of second semiconductor layer 103 is selected from one or more of AlInP, AlGaInP, GaP, GaN, InGaN, AlInGaN or AlGaN.

In some embodiments, micro LED element 100 includes a transparent conductive layer 104 formed on a top surface of first semiconductor layer 101 and is conductively coupled to first semiconductor layer 101. In some embodiments, transparent conductive layer 104 is provided as a TCO (transparent conductive oxide) layer, for example, an ITO (Indium Tin Oxide) layer, an AZO (Aluminium doped Zinc Oxide) layer, a GZO (Gallium doped Zinc Oxide), an ATO (Antimony doped Tin Oxide) layer, an FTO (Fluorine doped Tin Oxide) layer, or the like.

In some embodiments, a red micro LED element 100 may further a metal contact 110 on the top surface of first semiconductor layer 101 and is conductively coupled to first semiconductor layer 101. Metal contact 110 can be embedded in transparent conductive layer 104 for providing ohmic contact.

As shown in FIG. 1A, micro LED display panel 10 further includes an integrated circuit (IC) backplane 120 having a common pad (not shown) and a plurality of bottom contacts 121 for providing driving signals generated by IC backplane 120. Bottom contacts 121 are embedded in IC backplane 120 such that one bottom contact 121 corresponds to one micro LED element 100. Each of the plurality of micro LED elements 100 is disposed on a top surface of IC backplane 120. In the present disclosure, the top surface of IC backplane 120 is a surface that can be provided as a substrate for arranging components. As can be appreciated, the top surface, or its corresponding bottom surface on the opposite side, is typically larger than other sides of the IC backplane. In some embodiments, transparent conductive layer 104 can be connected to the common pad of IC backplane 120. In some embodiments, first semiconductor layer 101 of each of the plurality of micro LED elements 100 is conductively coupled to the common pad, and second semiconductor layer 103 of each of the plurality of micro LED elements 100 is conductively coupled to a corresponding bottom contact 121 of the plurality of bottom contacts 121. In some embodiments, IC backplane 120 can be a TFT (Thin Film Transistor) backplane.

FIG. 1B illustrates a structural diagram showing a top view of micro LED display panel 10 shown in FIG. 1A, according to some embodiments of the present disclosure. Some components have been omitted from FIG. 1B to more clearly illustrate particular features. In some embodiments, as transparent conductive layers 104 of all of micro LED elements 100 are formed as a continuous layer, the tops of all micro LED elements 100 are electrically connected, and one of the driving signals to a target micro LED element 100 can be received via corresponding bottom contact 121 of the target micro LED element 100 and the continuous transparent conductive layer 104, for example. As shown in FIG. 1B, transparent conductive layer 104 of micro LED element 100 can be a square having a center aligned with a center of light emitting layer 102 of micro LED element 100 when viewed from above. Transparent conductive layers 104 of respective micro LED elements 100 are seamlessly arranged to form the continuous transparent conductive layer 104.

Referring back to FIG. 1A, each contact pad 105 can be arranged between adjacent micro LED elements 100 and conductively coupled to respective first semiconductor layers 101 of adjacent micro LED elements 100 via transparent conductive layer 104. In some embodiments, the term “arrange” may also be referred to as “deploy,” “dispose” or an equivalent. As can be seen from FIG. 1A, only some of adjacent micro LED elements 100 (e.g., the left two adjacent micro LED elements 100 shown in FIG. 1A) are provided with contact pad 105 therebetween, while other adjacent micro LED elements 100 (e.g., the right two adjacent micro LED elements 100 shown in FIG. 1A) may not be provided with contact pad 105 therebetween. As can be understood, contact pads 105 provided within micro LED display panel 10 may shade the emitted light from light emitting layers 102 of respective micro LED elements 100 and thus affect the light extraction efficiency of micro LED display panel 10. A sparse arrangement of providing contact pads 105 only between some of adjacent micro LED elements 100 can reduce the shading effect and thus increase light extraction from mesa 130. Consequently, an improvement in light energy power and an increase in light extraction efficiency can be expected at a viewer's eye. For example, when micro LED display panel 10 is incorporated into a pair of AR/VR glasses, the luminance of micro LED display panel 10 can be higher when coupling to a waveguide of the AR/VR glasses, as compared with conventional designs. Moreover, some of contact pads 105 provided below can be used to increase current expansion (also referred to as “current spreading”) between adjacent micro LED elements 100 and subsequently improve current electrical spreading across micro LED display panel 10. Contact pads 105 can be formed in a variety of ways. For example, contact pads 105 can be deposited on transparent conductive layers 104 of adjacent micro LED elements 100 by sputtering or electron-beam deposition.

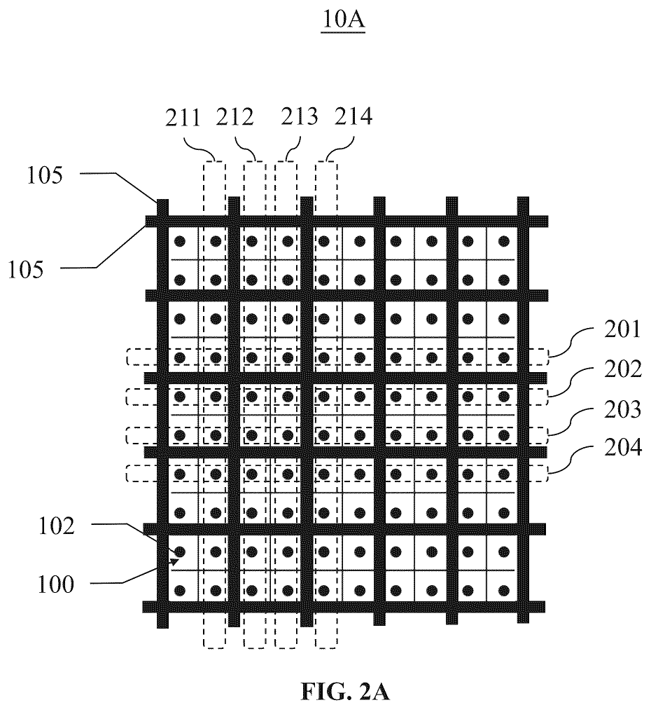

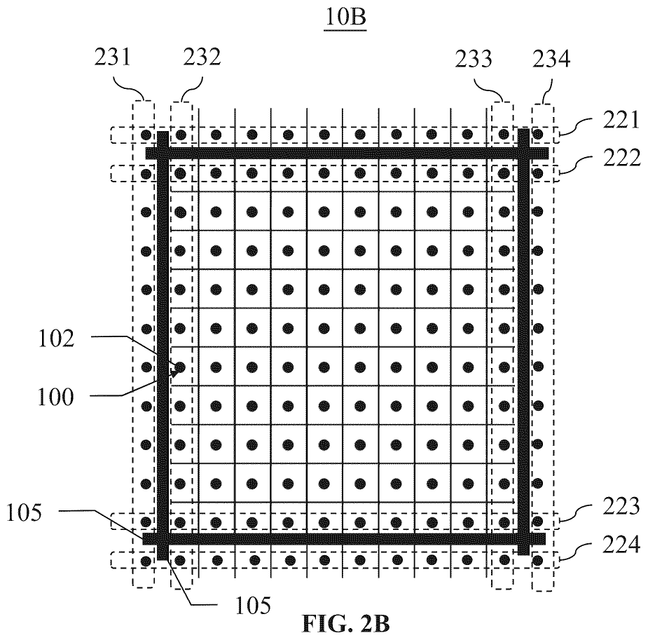

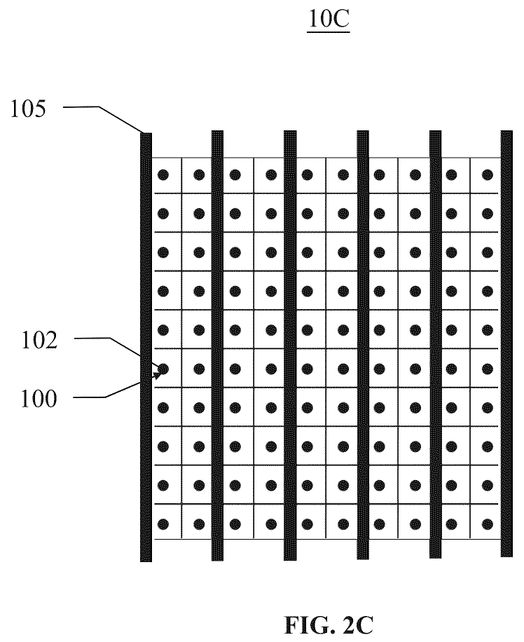

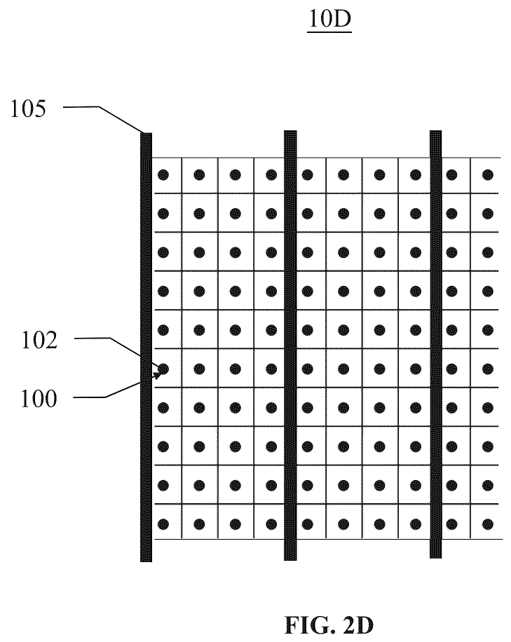

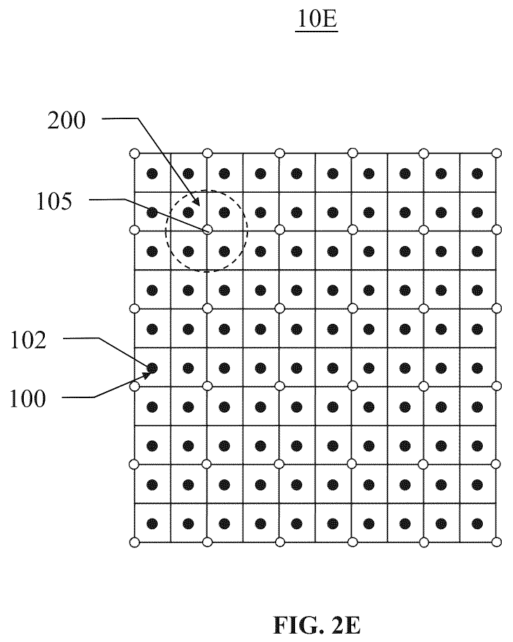

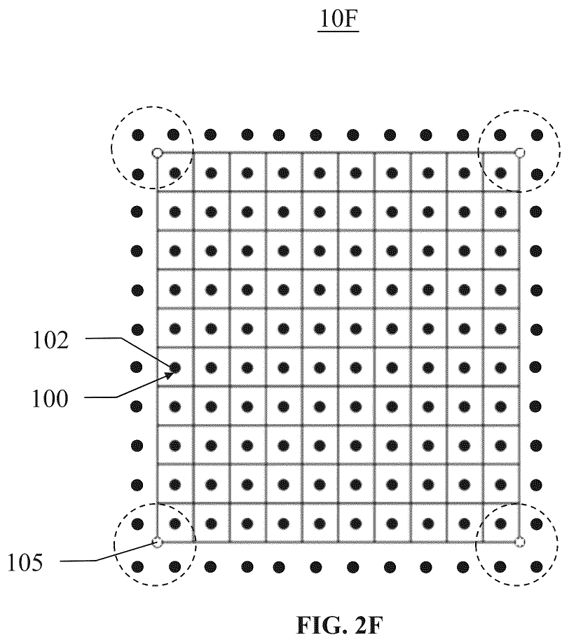

FIGS. 2A to 2F respectively illustrate structural diagrams each showing a top view of an exemplary micro LED display panel, according to some embodiments of the present disclosure. As shown in FIGS. 2A to 2F, micro LED elements 100, which are used provided with contact pads 105 therebetween, can be selected from micro LED elements 100 within micro LED display panel 10 (e.g., micro LED display panel 10A, 10B, 10C, 10D, 10E, or 10F shown in FIGS. 2A to 2F, respectively) according to a predetermined decimation rule. The present disclosure does not limit the expression or the format of the decimation rule as long as micro LED elements 100 can be selected accordingly. In some embodiments, micro LED elements 100 can be arranged in an array with several rows and columns. The selected micro LED elements 100 may comprise target rows or target columns of micro LED elements 100 within micro LED display panel 10 (e.g., as in micro LED display panel 10A, 10B, or 10C). In some embodiments, the selected micro LED elements 100 may comprise specific groups of micro LED elements 100 within micro LED display panel 10 (e.g., as in micro LED display panel 10D, 10E or 10F) that are selected according to the decimation rule, wherein each group of micro LED elements 100 can be adjacent.

As shown in FIGS. 2A to 2D, contact pads 105 disposed between the selected micro LED elements 100 may be connected to each other to form a linear conductor that is disposed along a line when viewed from above. That is, the connected contact pads 105 are disposed to form a conductive line, i.e., a linear conductor, between the selected micro LED elements 100 to increase current expansion. For example, the connected contact pads 105 can form a linear conductor between adjacent target rows of micro LED elements 100 or a linear conductor between adjacent target columns of micro LED elements 100. In some embodiments, as shown in FIG. 2A, a row 201 and an adjacent row 202 below row 201 can be selected as target rows of micro LED elements 100. Similarly, a row 203 that is two rows spaced from row 201 and an adjacent row 204 below row 203 can be selected as target rows of micro LED elements 100, and so on. The connected contact pads 105 forming each of the linear conductors can be disposed between rows 201 and 202, and between rows 203 and 204, and so on. Similarly, a column 211 and an adjacent column 212 to the right of column 211 can be selected as target columns of micro LED elements 100. Similarly, a column 213 that is two columns spaced from column 211 and an adjacent column 214 to the right of column 213 can be selected as target columns of micro LED elements 100, and so on. The connected contact pads 105 can be disposed between columns 211 and 212 to form a linear conductor, and between columns 213 and 214, and so on. As such, the connected contact pads 105 are disposed with a two-row spacing or pitch, or a two-column spacing or pitch.

In some embodiments, the deployment of contact pads 105 can be sparser. For example, as shown in FIG. 2B, a row 221 and an adjacent row 222 below row 221 can be selected as target rows of micro LED elements 100, and a row 223 that is ten rows spaced from row 221 and an adjacent row 224 below row 223 can be selected as target rows of micro LED elements 100, and so on. The connected contact pads 105 can be disposed to form a linear conductor between rows 221 and 222, and between rows 223 and 224, and so on. Similarly, a column 231 and an adjacent column 232 to the right of column 231 can be selected as target columns of micro LED elements 100, and a column 233 that is ten columns spaced from column 231 and an adjacent column 234 to the right of column 233 can be selected as target columns of micro LED elements 100, and so on. The connected contact pads 105 can be disposed to form a linear conductor between columns 231 and 232, and between columns 233 and 234, and so on. As such, the connected contact pads 105 are disposed with a ten-row spacing or pitch or a ten-column spacing or pitch.

In some embodiments, the deployment of contact pads 105 can be in either rows or columns. For example, the connected contact pads 105 can be disposed between target columns of micro LED elements 100 with a two-column spacing or pitch, as shown in FIG. 2C. In some embodiments, the deployment of contact pads 105 can be sparser. For example, the connected contact pads 105 can be disposed between target columns of micro LED elements 100 with a four-column spacing or pitch as shown in FIG. 2D. In some embodiments, the connected contact pads 105 can be disposed with an irregular spacing or pitch. That is, the connected contact pads 105 can be disposed with different spacings between the nearest two linear conductors.

In some embodiments, contact pads 105 can be disposed at discrete points such that they may not be shown in the sectional view in FIG. 1A. For example, as shown in FIG. 2E, the selected micro LED elements 100 may comprise several groups of four adjacent micro LED elements 100, each group forming a square. For example, a group 200 of micro LED elements 100, denoted by a dashed circle, may include four adjacent micro LED elements 100 which forms a square. In some embodiments, each micro LED element 100 is only included in one group. That is, all micro LED elements 100 of micro LED display panel 10D are selected and allocated for disposing contact pads 105. The distance between contact pads 105 can be two micro LED elements 100 in a row and a column. As can be understood, contact pads 105 disposed at a discrete point between four adjacent micro LED elements 100 of a respective group, i.e., disposed at the center of the square formed by four adjacent micro LED elements 100, can be sparser than the linear conductor arrangement described above. Consequently, contact pads 105 disposed at discrete points with a smaller volume may shade light less than linear conductors.

In some embodiments, contact pads 105 can be disposed to be sparser. As shown in FIG. 2F, each contact pads 105 is disposed at a center of a group of four adjacent micro LED elements 100. The groups of four adjacent micro LED elements 100 denoted by dashed circles are spaced with a distance of ten micro LED elements along rows and columns. That is, not all micro LED elements 100 of micro LED display panel 10D are allocated for being disposed adjacent to contact pads 105, and some of micro LED elements 100 are not selected for including in the groups. In some embodiments, contact pads 105 can be disposed unevenly. That is, the respective groups of four adjacent micro LED elements 100 can be selected in an uneven manner.

Referring back to FIG. 1A, micro LED element 100 further includes a connecting layer 106 (also referred to herein as a contact pad) that is conductively coupled to second semiconductor layer 103 and connected to bottom contact 121 (e.g., a Cu pad) of IC backplane 120. Hence, transparent conductive layer 104 and connecting layer 106 are respectively connected to two electrodes of IC backplane 120 either directly or indirectly. This enables first semiconductor layer 101 and second semiconductor layer 103 to receive signals from IC backplane 120 via transparent conductive layer 104 and connecting layer 106, respectively. As a consequence, light emitting layer 102 between first semiconductor layer 101 and second semiconductor layer 103 of each micro LED element 100 can be driven by IC backplane 120. In some embodiments, a diameter of bottom contact 121 is less than a diameter of connecting layer 106 for the convenience of arranging micro LED element 100 onto IC backplane 120. In addition, a diameter of first semiconductor layer 101 can be less than a diameter of second semiconductor layer 103 to facilitate forming each micro LED element 100.

In some embodiments, the sidewall of mesa 130 inclines so that mesa 130 gradually becomes narrower from bottom to top. The inclined sidewall can be generated in various other forms which are not described herein. The principal description above can also be applied to these variants.

As mesa 130 can be formed by etching at certain angles, the widths of different layers will be different due to the etching mechanism. In an etching process, the upper layers are made narrower than the lower layers. In some embodiments, the diameter of the top surface of mesa 130 can be similar to, or the same as, the diameter of the bottom surface. That is, the sidewall of mesa can be almost vertical.

With further reference to FIG. 1A, a sidewall surface of mesa 130 is covered with a passivation layer 107 for providing electrical insulation to the components within mesa 130. Passivation layer 107 of each micro LED element 100 is also extended to contact passivation layer 107 of an adjacent micro LED element 100. The thickness of passivation layer 107 is in a range of 3 nm to 15 nm for a bule micro LED element 100 or a green micro LED element 100, e.g., the thickness of passivation layer 107 can be 3 nm, 4 nm, 5 nm, 6 nm, 7 nm, 8 nm, 9 nm, 10 nm, 11 nm, 12 nm, 13 nm, 14 nm, or 15 nm. Alternatively, the thickness of passivation layer 107 can be several hundred nanometers for a red micro LED element 100. In some examples, passivation layer 107 is an ALD (Atomic Layer Deposition)-based layer or formed by plasma-enhanced chemical vapor deposition (PECVD). A material of passivation layer 107 can be selected from one or more of Al₂O₃, HfN, SiO₂, or SiN. Passivation layer 107 is used as a thin dielectric layer. It prevents short circuiting between first semiconductor layer 101 and second semiconductor layer 103, each provided as an N-type epitaxial layer or P-type epitaxial layer, as described above, and passivates dangling bonds on mesa sidewalls to reduce leakage current in micro LED element 100. As shown in FIG. 1A, passivation layer 107 can also be deposited in a region of the top surface of mesa 130, specifically a periphery of the top surface of first semiconductor layer 101. As can be appreciated, light emitted from light emitting layer 102 can be reflected by second semiconductor layer 103 and passivation layer 107 and emitted from a top of mesa 130.

In some embodiments, transparent conductive layer 104 can be formed on the top surface of mesa 130 in the region that is not deposited with passivation layer 107. Transparent conductive layer 104 can be further formed on a surface of the passivation layer 107 in the process of deposition. Thus, transparent conductive layer 104 can be conductively coupled to first semiconductor layer 101.

In some embodiments, mesa 130 may further include a transparent conductive layer 108 for conductively connecting second semiconductor layer 103 and connecting layer 106. In some embodiments, transparent conductive layer 108 can be formed with the same material as transparent conductive layer 104. Second semiconductor layer 103 is formed on a top surface of transparent conductive layer 108. Light emitting layer 102 is formed on second semiconductor layer 103, and first semiconductor layer 101 is formed on light emitting layer 102.

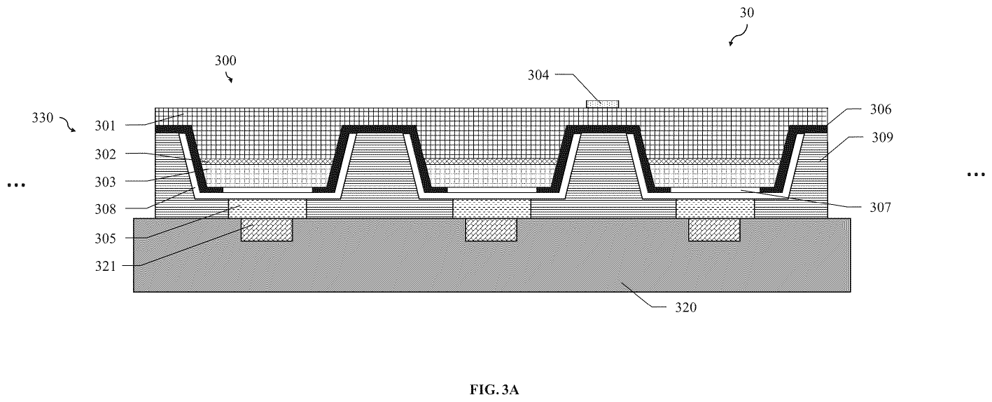

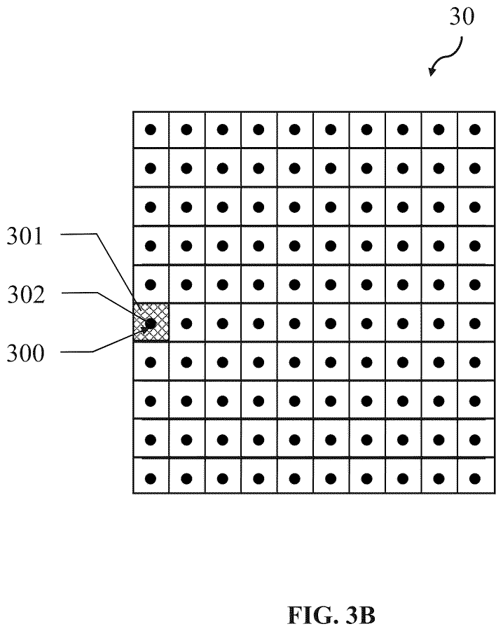

FIG. 3A illustrates a structural diagram showing a sectional view of another exemplary micro LED display panel 30, according to some embodiments of the present disclosure. Micro LED display panel 30 includes a plurality of micro LED elements 300 and a plurality of contact pads 304. It can be understood that in FIG. 3A, micro LED display panel 30 including three micro LED elements 300 and one contact pad 304 is shown only for illustrative purposes. The structure shown can be extended to form a complete micro LED display panel 30.

As shown in FIG. 3A, each micro LED element 300 includes a first semiconductor layer 301, a light emitting layer 302, and a second semiconductor layer 303. First semiconductor layer 301, light emitting layer 302, and second semiconductor layer 303 are stacked from top down to form a mesa 330. The sidewall of mesa 330 inclines so that mesa 330 gradually becomes broader from bottom to top. The inclined sidewall can be generated in various other forms which are not described herein. The principal description above can also be applied to these variants.

In some embodiments, second semiconductor layer 303 can be a P-type epitaxial layer or an N-type epitaxial layer. First semiconductor layer 301 can be an N-type epitaxial layer or a P-type epitaxial layer. A material of first semiconductor layer 301 is selected from one or more of GaN, InGaN, AlInGaN, AlGaN, GaP, AlGaInP, or AlInP. Light emitting layer 302 is a quantum well layer. A material of light emitting layer 302 is selected from one or more of InGaN, AlGaN, AlInGaN, InGaP or AlGaInP. First semiconductor layer 301 and second semiconductor layer 303 have opposite conductive types. That is, if first semiconductor layer 301 is a P-type epitaxial layer, then second semiconductor layer 303 is an N-type epitaxial layer; and if first semiconductor layer 301 is an N-type epitaxial layer, then second semiconductor layer 303 is a P-type epitaxial layer. A material of second semiconductor layer 303 is selected from one or more of AlInP, AlGaInP, GaP, GaN, InGaN, AlInGaN or AlGaN.

FIG. 3B illustrates a structural diagram showing a top view of micro LED display panel 30 shown in FIG. 3A, according to some embodiments of the present disclosure. Some components have been omitted from FIG. 3B to more clearly illustrate particular features. In some embodiments, as first semiconductor layers 301 of all of micro LED elements 300 are formed as a continuous layer, the tops of all micro LED elements 300 are electrically connected, and a driving signal to a target one of micro LED elements 300 can be received via a corresponding bottom contact 321 of the target micro LED element 300 and the continuous first semiconductor layer 301, for example. That is, all micro LED elements 300 share a common first semiconductor layer 301. As shown in FIG. 3B, first semiconductor layer 301 of micro LED element 300 can be a square having a center aligned with a center of light emitting layer 302 of micro LED element 300 when viewed from above. First semiconductor layers 301 of respective micro LED elements 300 are seamlessly arranged to form the continuous first semiconductor layer 301.

Referring back to FIG. 3A, the arrangement of contact pads 304 is a sparse arrangement of the contact pads, and the degree of sparsity can be determined according to actual needs or physical restrictions. The sparse arrangement can reduce a shading effect and thus increase the light extraction from mesa 330. As can be appreciated, in some embodiments, contact pads 304 can be disposed in a similar manner according to any of the deployments of contact pads 105 illustrated in FIGS. 2A to 2D to increase current expansion. For example, the connected contact pads 304 can be disposed between target rows of micro LED elements 300 or target columns of micro LED elements 300. The deployment of contact pads 304 will not be described in detail here.

In some embodiments, as shown in FIG. 3A, contact pads 304 can be arranged on the continuous first semiconductor layer 301 of micro LED elements 300. Specifically, contact pads 304 are disposed between selected adjacent micro LED elements 300.

As shown in FIG. 3A, each contact pad 304 can be disposed between adjacent micro LED elements 300. In addition, contact pad 304 is disposed on and conductively coupled to respective first semiconductor layers 301 of adjacent micro LED elements 300. As can be seen from FIG. 3A, only some of adjacent micro LED elements 300 (e.g., the right two adjacent micro LED elements 300 shown in FIG. 3A) are provided with contact pad 304 therebetween, while other adjacent micro LED elements 300 (e.g., the left two adjacent micro LED elements 300 shown in FIG. 3A) may not be provided with contact pad 304 therebetween. As can be understood, contact pads 304 disposed within micro LED display panel 30 may shade the emitted light from light emitting layers 302 and thus affecting the lighting efficiency. The sparse arrangement of disposing contact pads 304 between some of adjacent micro LED elements 300 can reduce the shading effect, and thus increasing light extraction from mesa 330. Consequently, an improvement in light energy power and an increase in light extraction efficiency can be expected at a viewer's eye. For example, when micro LED display panel 30 is incorporated into a pair of AR/VR glasses, the luminance of micro LED display panel 30 is higher when coupling to a waveguide of the AR/VR glasses, as compared with conventional designs. Contact pads 304 can be formed in a variety of ways. For example, contact pads 304 can be deposited on first semiconductor layers 301 of adjacent micro LED elements 300 by sputtering or electron-beam deposition.

As shown in FIG. 3A, micro LED display panel 30 further includes an IC backplane 320 having a common pad (not shown) and a plurality of bottom contacts 321 for providing driving signals generated by IC backplane 320. Each of the plurality of micro LED elements 300 is disposed on a top surface of IC backplane 320. In some embodiments, the continuous first semiconductor layer 301 of the plurality of micro LED elements 300 is conductively coupled to the common pad, and second semiconductor layer 303 of each of the plurality of micro LED elements 300 is conductively coupled to a corresponding bottom contact 321 of the plurality of bottom contacts 321. In some embodiments, IC backplane 320 can be a TFT (Thin Film Transistor) backplane.

As shown in FIG. 3A, micro LED element 300 further includes a connecting pad 305 (also referred to herein as a contact pad) that is conductively coupled to second semiconductor layer 303 and connected to bottom contact 321 (e.g., a Cu pad) of IC backplane 320. Hence, first semiconductor layer 301 and connecting pad 305 are respectively connected to two electrodes of IC backplane 320 either directly or indirectly. This enables first semiconductor layer 301 and second semiconductor layer 303 to receive signals from IC backplane 320. As a consequence, light emitting layer 302 between first semiconductor layer 301 and second semiconductor layer 303 can be driven by IC backplane 320.

As mesa 330 can be formed by etching at certain angles, the widths of different layers will be different due to the etching mechanism. In an etching process, the upper layers are made broader than the lower layers. In some embodiments, the diameter of the top surface of mesa 330 can be similar to, or the same as, the diameter of the bottom surface. That is, the sidewall of mesa can be almost vertical.

With further reference to FIG. 3A, a sidewall surface of mesa 330 is covered with a passivation layer 306 for providing electrical insulation to the components within mesa 330. Passivation layer 306 is also extended to contact passivation layer 306 of an adjacent micro LED element 300. The thickness of passivation layer 306 is in a range of 3 nm to 15 nm for a bule micro LED element 300 or a green micro LED element 300, e.g., the thickness of passivation layer 306 can be 3 nm, 4 nm, 5 nm, 6 nm, 7 nm, 8 nm, 9 nm, 10 nm, 11 nm, 12 nm, 13 nm, 14 nm, or 15 nm. Alternatively, the thickness of passivation layer 306 can be several hundred nanometers for a red micro LED element 300. In some examples, passivation layer 306 is an ALD (Atomic Layer Deposition)-based layer or formed by plasma-enhanced chemical vapor deposition (PECVD). A material of passivation layer 306 can be selected from one or more of Al₂O₃, HIN, SiO₂, or SiN. Passivation layer 306 is used as a thin dielectric layer. It prevents short circuiting between of first semiconductor layer 301 and second semiconductor layer 303, each provided as an N-type epitaxial layer or P-type epitaxial layer, as described above, and passivates dangling bonds on mesa sidewalls to reduce leakage current in micro LED element 300.

In some embodiments, mesa 330 may further include a transparent conductive layer 307 for conductively connecting second semiconductor layer 303 and connecting pad 305. In some embodiments, transparent conductive layer 307 is provided as a TCO (transparent conductive oxide) layer, for example, an ITO (Indium Tin Oxide) layer, an AZO (Aluminium doped Zinc Oxide) layer, a GZO (Gallium doped Zinc Oxide), an ATO (Antimony doped Tin Oxide) layer, an FTO (Fluorine doped Tin Oxide) layer, or the like. Second semiconductor layer 303 is formed on a top surface of transparent conductive layer 307. Light emitting layer 302 is formed on second semiconductor layer 303, and first semiconductor layer 301 is formed on light emitting layer 302. Contact pads 304 are arranged on the respective first semiconductor layers 301 of the adjacent micro LED elements 300.

In some embodiments, micro LED element 300 may further include metal reflective layer 308 formed on a bottom surface of second transparent conductive layer 307. Connecting pad 305 can be formed on a bottom surface of the metal reflective layer 308. To improve light emission efficiency, metal reflective layer 308 is provided to reflect light upwards as viewed in FIG. 3A. Metal reflective layer 308 may be made of Ag, Al, Au, etc., and coated with one or more of Cr, Ni, Pt, Ti, or Au. In some embodiments, metal reflective layer 308 is further extended to and formed on a surface of passivation layer 306. Passivation layer 306 is provided between metal reflective layer 308 and second semiconductor layer 303.

With further reference to FIG. 3A, micro LED element 300 further includes an insulating layer 309 formed on IC backplane 320. Insulating layer 309 covers IC backplane 320 and provides insulation to surface components of IC backplane 320. In addition, insulating layer 309 can support metal reflective layers 308 and passivation layers 306.

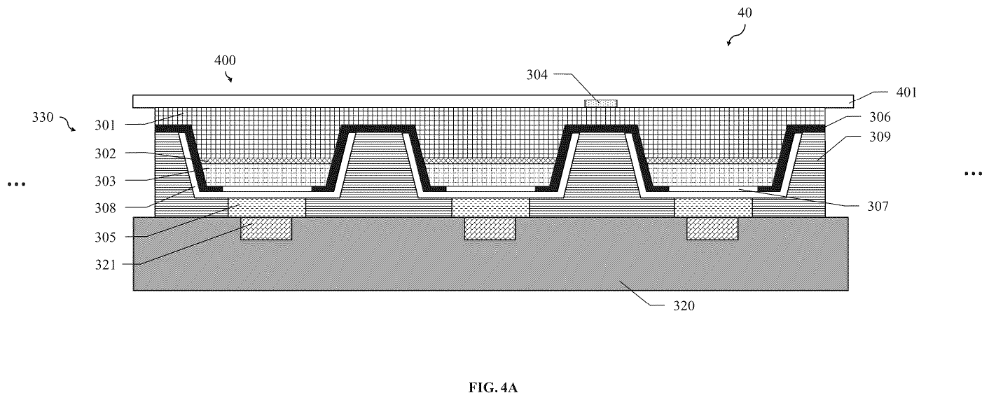

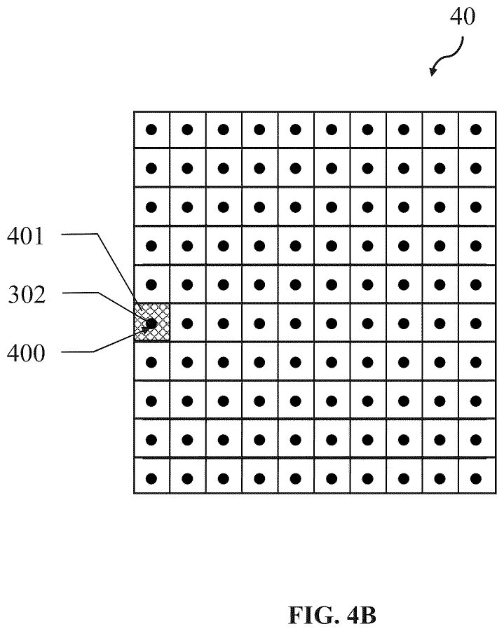

FIG. 4A illustrates a structural diagram showing a sectional view of another exemplary micro LED display panel 40, according to some embodiments of the present disclosure. It can be understood that in FIG. 4A, micro LED display panel 40 including three micro LED elements 400 and one contact pad 304 is shown only for illustrative purposes. The structure shown can be extended to form a complete micro LED display panel 40.

As shown in FIG. 4A, micro LED display panel 40 may include a transparent conductive layer 401 formed on a top surface of first semiconductor layer 301 and is conductively coupled to first semiconductor layer 301. In some embodiments, transparent conductive layer 401 is provided as a TCO (transparent conductive oxide) layer, for example, an ITO (Indium Tin Oxide) layer, an AZO (Aluminium doped Zinc Oxide) layer, a GZO (Gallium doped Zinc Oxide), an ATO (Antimony doped Tin Oxide) layer, an FTO (Fluorine doped Tin Oxide) layer, or the like. Contact pads 304 can be embedded in transparent conductive layers 401 of the adjacent micro LED elements 400. As can be appreciated, contact pads 304 are provided as an ohmic contact layer between first semiconductor layer 301 and transparent conductive layer 401 to improve the electrically connecting performance.

FIG. 4B illustrates a structural diagram showing a top view of micro LED display panel 40 shown in FIG. 4A, according to some embodiments of the present disclosure. Some components have been omitted from the FIG. 4B to more clearly illustrate particular features. In some embodiments, as transparent conductive layers 401 of all of micro LED elements 400 are formed as a continuous layer, the tops of all micro LED elements 400 are electrically connected, and a driving signal to a target micro LED element 400 can be received via corresponding bottom contact 321 of the target micro LED element 400 and the continuous transparent conductive layer 401, for example. As shown in FIG. 4B, transparent conductive layer 401 of micro LED element 400 can be a square having a center aligned with a center of light emitting layer 302 of micro LED element 400 when viewed from above. Transparent conductive layers 401 of respective micro LED elements 400 are seamlessly arranged to form the continuous transparent conductive layer 401.

The other aspects of micro LED display panel 40 are the same as described above for micro LED display panel 30 with reference to FIGS. 3A and 3B and will not be described in detail here.

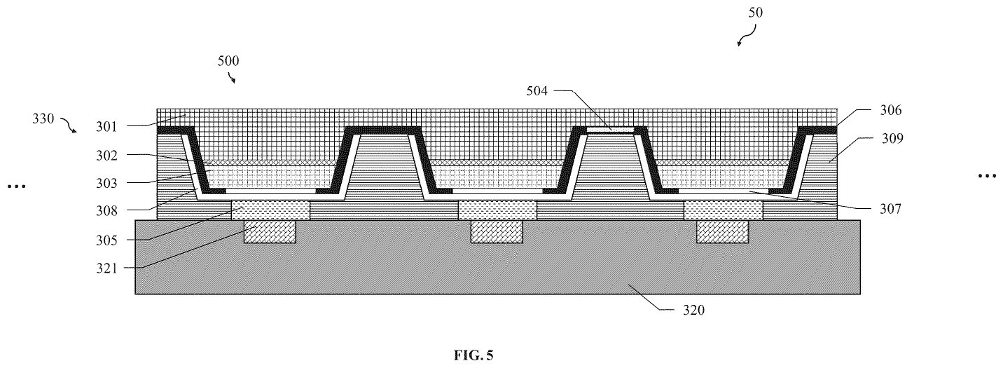

FIG. 5 illustrates a structural diagram showing a sectional view of another exemplary micro LED display panel 50, according to some embodiments of the present disclosure. It can be understood that in FIG. 5, micro LED display panel 50 including three micro LED elements 500 and one contact pad 504 is shown only for illustrative purposes. The structure shown can be extended to form a complete micro LED display panel 50. As shown in FIG. 5, contact pads 504 can be embedded in passivation layers 306 of adjacent micro LED elements 500. In some embodiments, contact pads 504 are aligned with each other, and a top surface of each contact pad 504 is aligned with a top surface of passivation layer 306.

Still referring to FIG. 5, the arrangement of contact pads 504 is a sparse arrangement of the contact pads, and the degree of sparsity can be determined according to actual needs or physical restrictions. The sparse arrangement can reduce a shading effect, and thus increasing the light extraction from mesa 330. As can be appreciated, contact pads 504 can be disposed in a similar manner according to any of the arrangements of contact pads 105 illustrated in FIGS. 2A to 2D to increase current expansion. For example, the connected contact pads 504 can be disposed between target rows of micro LED elements 500 or between target columns of micro LED elements 500. The arrangement of contact pads 504 will not be further described here.

The other aspects of micro LED display panel 50 can be referred to micro LED display panel 30 described above with reference to FIGS. 3A and 3B and will not be described in detail here.

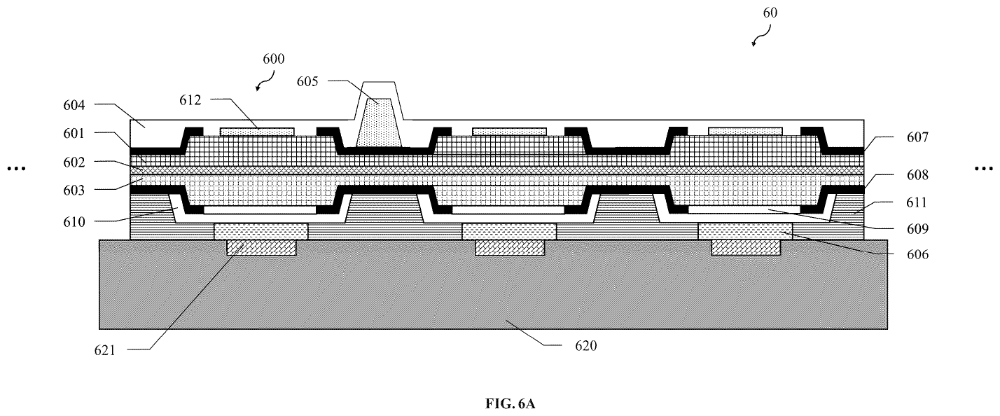

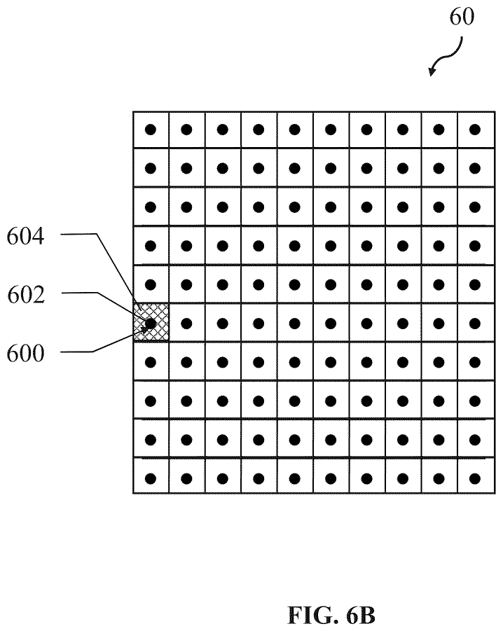

FIG. 6A illustrates a structural diagram showing a sectional view of another exemplary micro LED display panel 60, according to some embodiments of the present disclosure. It can be understood that in FIG. 6A, micro LED display panel 60 including three micro LED elements 600 and one contact pad 605 is shown only for illustrative purposes. The structure shown can be extended to form a complete micro LED display panel 60.

Referring to FIG. 6A, micro LED element 600 includes a first semiconductor layer 601, a light emitting layer 602, and a second semiconductor layer 603. First semiconductor layer 601, light emitting layer 602, and second semiconductor layer 603 are stacked from top down to form a mesa with a different shape than that shown in FIGS. 1A to 5. As shown in FIG. 6A, the mesa is formed into an olive shape with respective first semiconductor layer 601 and second semiconductor layer 603 decreasing in thickness at their ends and on either side of light emitting layer 602. Hence, the corresponding mid-portions of first semiconductor layer 601 and second semiconductor layer 603 are thicker than corresponding end portions.

In some embodiments, second semiconductor layer 603 can be a P-type epitaxial layer or an N-type epitaxial layer. First semiconductor layer 601 is an N-type epitaxial layer or a P-type epitaxial layer. A material of first semiconductor layer 601 is selected from one or more of GaN, InGaN, AlInGaN, AlGaN, GaP, AlGaInP, or AlInP. Light emitting layer 602 is a quantum well layer. A material of light emitting layer 602 is selected from one or more of InGaN, AlGaN, AlInGaN, InGaP or AlGaInP. First semiconductor layer 601 and second semiconductor layer 603 have opposite conductive types. That is, if first semiconductor layer 601 is a P-type epitaxial layer, then second semiconductor layer 603 is an N-type epitaxial layer; and if first semiconductor layer 601 is an N-type epitaxial layer, then second semiconductor layer 603 is a P-type epitaxial layer. A material of second semiconductor layer 603 is selected from one or more of AlInP, AlGaInP, GaP, GaN, InGaN, AlInGaN or AlGaN.

As shown in FIG. 6A, micro LED element 600 further includes a transparent conductive layer 604 formed on a top surface of first semiconductor layer 601 and is conductively coupled to first semiconductor layer 601. In some embodiments, as transparent conductive layers 604 of all of micro LED elements 600 are formed as a continuous layer, the tops of all micro LED elements 600 are electrically connected. Transparent conductive layer 604 can be connected to an electrode (e.g., a common pad, not shown) of an IC backplane 620. In some embodiments, transparent conductive layer 604 is provided as a TCO (transparent conductive oxide) layer, for example, an ITO (Indium Tin Oxide) layer, an AZO (Aluminium doped Zinc Oxide) layer, a GZO (Gallium doped Zinc Oxide), an ATO (Antimony doped Tin Oxide) layer, an FTO (Fluorine doped Tin Oxide) layer, or the like. In some embodiments, IC backplane 620 can be a TFT (Thin Film Transistor) backplane.

FIG. 6B illustrates a structural diagram showing a top view of micro LED display panel 60 shown in FIG. 6A, according to some embodiments of the present disclosure. Some components have been omitted from the FIG. 6B to more clearly illustrate particular features. As described above, transparent conductive layers 604 of all of micro LED elements 600 can be formed as a continuous layer, the tops of all micro LED elements 600 are electrically connected, and a driving signal to a target micro LED element 600 can be received via corresponding bottom contact 621 of the target micro LED element 600 and the continuous transparent conductive layer 604, for example. As shown in FIG. 6B, the portion of continuous transparent conductive layer 604 corresponding to each micro LED element 600 can be viewed having a square shape with a center aligned with a center of light emitting layer 602 of micro LED element 600 when viewed from above. The portions of transparent conductive layer 604 corresponding to respective micro LED elements 600 are seamlessly arranged to form the continuous transparent conductive layer 604.

Referring back to FIG. 6A, IC backplane 620 has the common pad (not shown) and a plurality of bottom contacts 621 (e.g., a Cu pad) for providing driving signals generated by IC backplane 620. Bottom contacts 621 are embedded in IC backplane 620 such that one bottom contact 621 corresponds to one micro LED element 600. Each of the plurality of micro LED elements 600 is disposed on a top surface of IC backplane 620. In some embodiments, first semiconductor layer 601 of each of the plurality of micro LED elements 600 is conductively coupled to the common pad, and second semiconductor layer 603 of each of the plurality of micro LED elements 600 is conductively coupled to a corresponding bottom contact 621 of the plurality of bottom contacts 621.

As shown in FIG. 6A, each contact pads 605 can be embedded in continuous transparent conductive layer 604 between adjacent micro LED elements 600 and conductively coupled to respective first semiconductor layers 601 of the adjacent micro LED elements 600 via transparent conductive layer 604. As can be appreciated, in some embodiments, contact pads 605 can be disposed in a similar manner according to any of the arrangements of contact pads 105 illustrated by FIGS. 2A to 2D to increase current expansion. In some embodiments, contact pads 605 can be disposed according to the arrangements shown in FIGS. 2E and 2F. For example, the connected contact pads 605 can be disposed between target rows of micro LED elements 600 or target columns of micro LED elements 600. The arrangement of contact pads 304 will not be further described in detail here.

As shown in FIG. 6A, micro LED element 600 further includes a connecting pad 606 that is connected to bottom contact 621 of IC backplane 620. Hence, transparent conductive layer 604 and connecting pad 606 are connected to two electrodes of IC backplane 620. This enables first semiconductor layer 601 and second semiconductor layer 603 to receive signals from IC backplane 620. As a consequence, light emitting layer 602 between first semiconductor layer 601 and second semiconductor layer 603 can be driven by the signals from IC backplane 620.

As shown in FIG. 6A, light emitting layer 602 separates micro LED element 600 into two isolated parts. As for the part above light emitting layer 602, a passivation layer 607 is formed on a sidewall surface of first semiconductor layer 601. As for the part below light emitting layer 602, a passivation layer 608 is formed on a sidewall surface of second semiconductor layer 603. Passivation layers 607 and 608 can provide electrical insulation to the component they cover. The thickness of passivation layer 607 (608) is in a range of 3 nm to 15 nm for a bule micro LED element 600 or a green micro LED element 600, e.g., the thickness of passivation layer 607 (608) can be 3 nm, 4 nm, 5 nm, 6 nm, 7 nm, 8 nm, 9 nm, 10 nm, 11 nm, 12 nm, 13 nm, 14 nm, or 15 nm. Alternatively, the thickness of passivation layer 607 (608) can be several hundred nanometers for a red micro LED element 600. In some examples, passivation layer 607 (608) is an ALD-based layer or formed by plasma-enhanced chemical vapor deposition (PECVD). A material of passivation layer 607 (608) can be selected from one or more of Al₂O₃, HfN, SiO₂, or SiN. Passivation layer 607 (608) is used as a thin dielectric layer. As shown in FIG. 6A, passivation layer 607 can also be deposited in a region of the top surface of first semiconductor layer 601. As passivation layer 607 only covers an edge of the upper portion of first semiconductor layer 601, passivation layer 607 does not block light emitted from light emitting layer 602. In some embodiments, in the process of depositing transparent conductive layer 604, it can be then formed on the top surface of first semiconductor layer 601 in the region that is not deposited with passivation layer 607. In some embodiments, contact pads 605 can be formed (e.g., deposited) on passivation layer 607 of adjacent micro LED elements 600.

Still referring to FIG. 6A, micro LED element 600 further includes a transparent conductive layer 609 for conductively connecting second semiconductor layer 603 and connecting pad 606 through a metal reflective layer 610 further described below. For example, connecting pad 606 can be formed below transparent conductive layer 609. In some embodiments, second semiconductor layer 603 is formed on a top surface of transparent conductive layer 609. Light emitting layer 602 is formed on second semiconductor layer 603, and first semiconductor layer 601 is formed on light emitting layer 602. In some embodiments, transparent conductive layer 609 can be formed with the same material as transparent conductive layer 604.

Micro LED element 600 further includes metal reflective layer 610 formed on a bottom surface of second transparent conductive layer 609, wherein connecting pad 606 is formed on a bottom surface of the metal reflective layer 610. To improve light emission efficiency, metal reflective layer 610 is provided to reflect light upwards as viewed in FIG. 6A. Metal reflective layer 610 may be made of Ag, Al, Au, etc., and coated with one or more of Cr, Ni, Pt, Ti, or Au. In some embodiments, metal reflective layer 610 is further extended to and formed on a surface of passivation layer 608. Passivation layer 608 is provided between metal reflective layer 610 and second semiconductor layer 603.

With further reference to FIG. 6A, micro LED element 600 further includes an insulating layer 611 formed on IC backplane 620. Insulating layer 611 covers IC backplane 620 and provides insulation to surface components of IC backplane 620.

As shown in FIG. 6A, micro LED element 600 further includes a metal contact 612 (e.g., an AuGeAu metal contact) embedded in transparent conductive layer 604 which acts as an ohmic contact to increase the electrical conductivity between first semiconductor layer 601 and transparent conductive layer 604. Metal contact 612 can be formed on a top surface of first semiconductor layer 601.

The other aspects of micro LED display panel 60 can be understood by referring to the description of any of the micro LED display panels described above and will not be described in detail here.

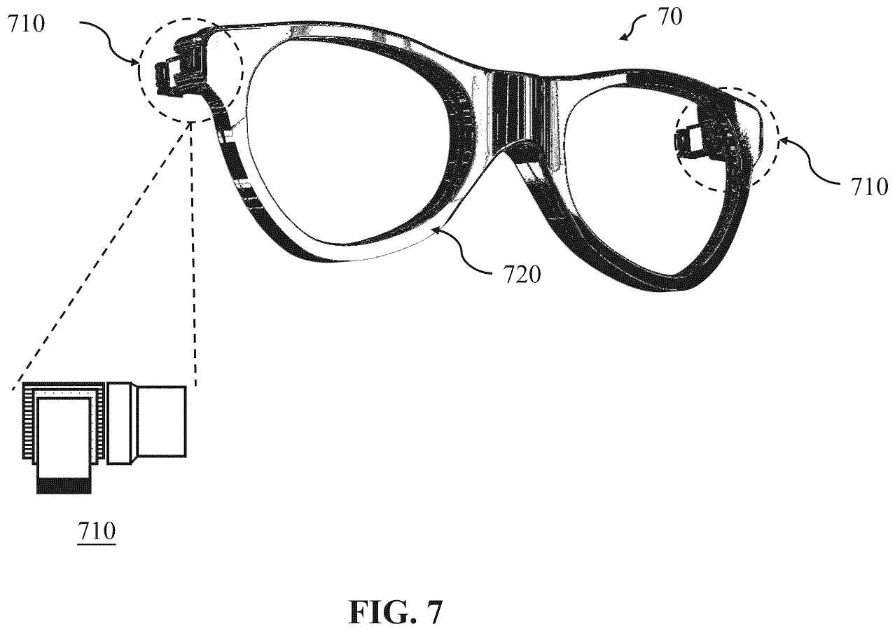

FIG. 7 illustrates an exemplary display device, according to some embodiments of the present disclosure. As shown in FIG. 7, a near eye display (NED) 70, for example AR glasses, includes a pair of polychrome projectors 710 and a frame 720 for securing polychrome projectors 710. NED 70 may also include other components which are omitted here for the purpose of clearly illustrating the configuration of NED 70. Each polychrome projector 710 can be arranged at an end of a temple (not shown) of NED 70, respectively. A power system and a processing system to drive polychrome projectors 710 can be embedded in the temple. Images rendered by each polychrome projector 710 can be captured by respective eyes of a viewer (not shown), which can be used to create a virtual scene or an augmented scene for the viewer. In some embodiments, the term “render” may also be referred to as “display,” “show” or an equivalent. Each polychrome projector 710 may include three micro LED panels (e.g., each corresponding to any of the micro LED display panels in FIGS. 1A to 6) of different colors and a combiner (e.g., a combining prism). The combiner can be used to combine (also referred to as “compositing”) the images rendered by the three micro LED panels into a composite image.

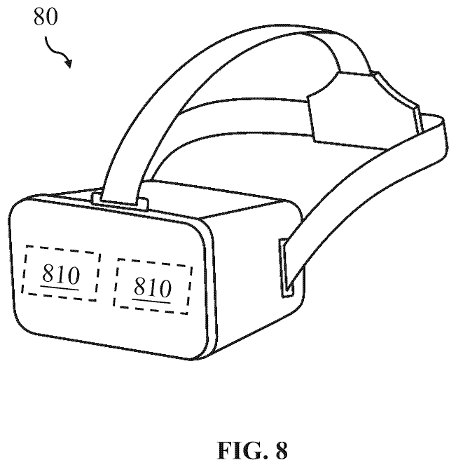

FIG. 8 illustrates another exemplary display device, according to some embodiments of the present disclosure. As shown in FIG. 8, a head-mounted virtual reality device 80 includes two micro LED panels 810 (e.g., each corresponding to any of the micro LED display panels in FIGS. 1A to 6). Although not shown, head-mounted virtual reality device 80 may also include a central processing unit (CPU), a graphic processing unit (GPU) acting as a signal source, and other related circuitries. The introduction of micro LED panels that embody the micro LED elements described above in head-mounted virtual reality device 80 can improve the lighting efficiency thereof, hence reducing energy consumption and improving imaging quality.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED display panel, comprising:
a plurality of micro LED elements each comprising a first semiconductor layer, a light emitting layer, and a second semiconductor layer stacked from top down; and
a plurality of contact pads each arranged between adjacent micro LED elements of a part of the plurality of micro LED elements and conductively coupled to the respective first semiconductor layers of the adjacent micro LED elements.

2. The micro LED display panel according to claim 1, wherein the part of the plurality of micro LED elements is selected, by a decimation rule, from the plurality of micro LED elements.

3. The micro LED display panel according to claim 2, wherein the plurality of micro LED elements are arranged in an array with rows and columns, and the part of the plurality of micro LED elements comprises target rows of micro LED elements or target columns of micro LED elements of the plurality of micro LED elements.

4. The micro LED display panel according to claim 3, wherein at least a part of the plurality of contact pads are connected to each other to form a linear conductor.

5. The micro LED display panel according to claim 2, wherein the plurality of micro LED elements are arranged in an array with rows and columns, and the part of the plurality of micro LED elements comprise groups of four adjacent micro LED elements, each group forming a square; and
wherein at least a part of the plurality of contact pads are arranged at a center of the four adjacent micro LED elements.

6. The micro LED display panel according to claim 1, wherein the plurality of contact pads are arranged on the respective first semiconductor layers of the adjacent micro LED elements.

7. The micro LED display panel according to claim 1, wherein the first semiconductor layer, the light emitting layer, and the second semiconductor layer are stacked as a mesa; and each of the plurality of micro LED elements further comprises:
a passivation layer formed on a sidewall surface of the mesa and extending to contact the passivation layer of an adjacent micro LED element; and
a transparent conductive layer formed on a top surface of the first semiconductor layer and a top surface of the passivation layer and connected to the transparent conductive layer of an adjacent micro LED element, wherein the plurality of contact pads are arranged on the transparent conductive layers of the adjacent micro LED elements.

8. The micro LED display panel according to claim 1, wherein the first semiconductor layer, the light emitting layer, and the second semiconductor layer are stacked as a mesa; and each of the plurality of micro LED elements further comprises:
a passivation layer formed on a sidewall surface of the mesa and extending to contact the passivation layer of an adjacent micro LED element, wherein the plurality of contact pads are embedded in the passivation layers of the adjacent micro LED elements.

9. The micro LED display panel according to claim 8, wherein a top surface of each of the plurality of contact pads is aligned with a top surface of the passivation layer.

10. The micro LED display panel according to claim 8, wherein the passivation layer is an ALD (Atomic Layer Deposition)-based layer.

11. The micro LED display panel according to claim 7, wherein the transparent conductive layer is a first transparent conductive layer, the mesa further comprising: a second transparent conductive layer formed on a bottom surface of the second semiconductor layer.

12. The micro LED display panel according to claim 11, wherein each of the plurality of micro LED elements further comprises:
a metal reflective layer formed on a bottom surface of the second transparent conductive layer; and
a connecting layer formed on a bottom surface of the metal reflective layer and conductively coupled to the second semiconductor layer.

13. The micro LED display panel according to claim 1, wherein each of the plurality of micro LED elements further comprises:
a transparent conductive layer formed on a top surface of the first semiconductor layer, wherein the plurality of contact pads are embedded in the transparent conductive layers of the adjacent micro LED elements.

14. The micro LED display panel according to claim 13, wherein each of the plurality of micro LED elements further comprises:
a first passivation layer formed on an edge of an upper portion of the first semiconductor layer; and
a second passivation layer formed on a bottom surface of the second semiconductor layer;
wherein the light emitting layers of the plurality of micro LED elements together form a continuous layer, and the plurality of contact pads are formed on the first passivation layers of the adjacent micro LED elements.

15. The micro LED display panel according to claim 14, wherein at least one of the first passivation layer and the second passivation layer is an ALD-based layer.

16. The micro LED display panel according to claim 14, wherein the transparent conductive layer is a first transparent conductive layer, and each of the plurality of micro LED elements comprises:
a second transparent conductive layer formed on a bottom surface of the second semiconductor layer; and
a connecting pad formed below the second transparent conductive layer and conductively coupled to the second semiconductor layer.

17. The micro LED display panel according to claim 16, wherein each of the plurality of micro LED elements comprises: a metal reflective layer formed on a bottom surface of the second transparent conductive layer, wherein the connecting pad is formed on a bottom surface of the metal reflective layer.

18. The micro LED display panel according to claim 17, wherein the metal reflective layer is further formed on a surface of the second passivation layer, the second passivation layer being provided between the metal reflective layer and the second semiconductor layer.

19. The micro LED display panel according to claim 14, wherein the plurality of micro LED elements each comprises a metal contact arranged on the first semiconductor layer.

20. The micro LED display panel according to claim 1, further comprising:
an integrated circuit (IC) backplane comprising a common pad and a plurality of bottom contacts providing a driving signal generated by the IC backplane; and
wherein the plurality of micro LED elements are disposed on a top surface of the IC backplane, the first semiconductor layers of the plurality of micro LED elements are conductively coupled to the common pad, and the second semiconductor layers of the plurality of micro LED elements are conductively coupled to a corresponding bottom contact of the plurality of bottom contacts.

21. A display device, comprising a micro LED display panel, wherein the micro LED display panel comprises:
a plurality of micro LED elements each comprising a first semiconductor layer, a light emitting layer, and a second semiconductor layer stacked from top down; and
a plurality of contact pads each arranged between adjacent micro LED elements of a part of the plurality of micro LED elements and conductively coupled to the respective first semiconductor layers of the adjacent micro LED elements.
